(19) United States
(12) Patent Application Publication
(10) Pub. No.: US 2002/0137340 A1
(43) Pub. Date: Sep. 26, 2002

(54) PLASMA ETCHING METHOD FOR SEMICONDUCTOR DEVICE AND ETCHING APPARATUS OF THE SAME

(76) Inventors: KIL-HO KIM, KWANGJU-KUN (KR); KYE-HYUN BAEK, BUCHEON-SHI (KR)

Correspondence Address: OLIFF & BERRIDGE, PLC, P.O. BOX 19928, ALEXANDRIA, VA, 22320, US

(21) Appl. No.: 09/221,992

(22) Filed: Dec. 29, 1998

(30) Foreign Application Priority Data
Dec. 31, 1997 (KR) 1997-82313

(51) Int. Cl. H01L 21/302; H01L 21/461

(52) U.S. Cl. 438/689

(57) ABSTRACT

A plasma etching method for a semiconductor apparatus and an etching apparatus of the same are disclosed. The plasma etching method for a semiconductor apparatus includes the steps of bypassing a light emitting signal of a wavelength band generated by a main composition forming a first thin film among the light emitting signals generated during the plasma etching process and converting the signal into a first electrical signal, bypassing a signal of a predetermined wavelength band near the wavelength band of the light emitting signal and converting the second electrical signal, and completing the plasma etching process based on a strength difference between the first and second electrical signals as a reference for thereby detecting timing that an etching reaches an interfacial surface between a first thin film and a second thin film which are sequentially stacked and timing that an etching reaches an interfacial surface between the second thin film and the lower film by adapting a light emitting signal of a predetermined wavelength generated by a main composition of an etching layer to an etching stop point measuring apparatus.

### BACKGROUND OF THE INVENTION

1. Field of the Invention

The present invention relates to a plasma etching method for a semiconductor devices, and in particular to an improved plasma etching method for a semiconductor device which is capable of accurately determining an etching timing of a thin film interface when etching a double thin film having different characteristics using a plasma, and in more particular to a plasma etching apparatus for a semiconductor device capable of implementing an accurate etching stop timing and simplifying the structure of a semiconductor device.

2. Description of the Conventional Art

In the fabrication process of a semiconductor device, a metal wiring technique adapting a structure in which an oxide film, a diffusion barrier, and a conductive layer are sequentially stacked is generally used. The conductive layer is a layer at which a current flows during the operation of the device and comprises mainly Al and a predetermined amount of Cu or Si. In addition, the oxide film serves to electrically insulate the metal wiring of the lower portion and the metal wiring of the upper portion and is formed of a silicon oxide film SiO₂₋ₓ which is a compound of a silicon and oxygen. The diffusion barrier formed between the oxide film and the conductive layer is directed to preventing a problem such as a spiking which occurs when aluminum is diffused into the oxide film and is generally formed of TiN. For a predetermined purpose, the structure of the above-descried metal wiring may be changed. However, almost parts of the above-described metal wiring structure is currently used for the fabrication of the semiconductor device.

FIG. 1 illustrates a metal wiring having a structure formed of an oxide film, diffusion barrier, conductive layer, and FIG. 2 is a perspective view of FIG. 2.

The fabrication process for forming a conventional metal wiring will be explained with reference to FIGS. 1 and 2.

First, a TiN thin film and Al layer are sequentially stacked on an oxide film. A photoresist film is coated on the thusly stacked Al layer, and a predetermined shaped photoresist pattern is formed based on the photolithography process. Thereafter, the metal formed on the portion in which the photoresist film is not formed is etched using the activated plasma, and the photoresist film covering the upper portion of the metal which is not etched is removed for thereby obtaining the structure, as shown in FIG. 2, in which the oxide film 10, the TiN film pattern 20 and the Al film pattern 30 are sequentially stacked.

When etching the metal using the photoresist pattern, the plasma state when etching the conductive layer mainly formed of Al is different from the plasma state when etching the diffusion barrier mainly formed of TiN for thereby obtaining an optimized etching state. Therefore, it is important to accurately determine timing that the etching reaches the interfacial surface between two metal layers. In addition, since the optimum metal etching process is directed to completely etching the diffusion barrier as well as minimizing the etching of the oxide film, it is needed to obtain a predetermined timing that the etching reaches the interfacial surface between the diffusion barrier and the oxide film.

In order to meet the above-described necessity, various types of the etching stop point measuring apparatus are adapted to the metal etching apparatus. However, an etching stop point measuring apparatus capable of detecting an interface between the conductive layer and the diffusion barrier and an interface between the diffusion barrier and the oxide film is not disclosed. In this case, the metal etching process is implemented based on a method in which the etching time is determined based on the experience of an operator or workers. This method requires an additional cost and labor-intensive process, and it is impossible to implement an accurate etching result.

### SUMMARY OF THE INVENTION

Accordingly, it is an object of the present invention to provide a plasma etching method for a semiconductor apparatus and an etching method of the same which overcome the aforementioned problems encountered in the conventional art.

It is another object of the present invention to provide a plasma etching method for a semiconductor apparatus and an etching apparatus of the same which are capable of detecting timing that an etching reaches an interfacial surface between a first thin film and a second thin film which are sequentially stacked and timing that an etching reaches an interfacial surface between the second thin film and the lower film by adapting a light emitting signal of a predetermined wavelength generated by a main composition of an etching layer to an etching stop point measuring apparatus.

It is another object of the present invention to provide a plasma etching method for a semiconductor apparatus and an etching apparatus of the same which makes it possible to uniformly measure an etching stop point without any effects by a plasma activation condition.

In order to achieve the above objects, there is provided a plasma etching method for a semiconductor apparatus which includes the steps of bypassing a light emitting signal of a wavelength band generated by a main composition forming a first thin film among the light emitting signals generated during the plasma etching process and converting the signal into a first electrical signal, bypassing a signal of a predetermined wavelength band near the wavelength band of the light emitting signal and converting the second electrical signal, and completing the plasma etching process based on a strength difference between the first and second electrical signals as a reference.

The first thin film is a diffusion barrier, and the second thin film is a metal film, and the diffusion barrier is formed of TiN. In addition, the light emitting signal generated by a main composition forming the diffusion barrier is a light emitting signal from Ti or TiCl.

In order to achieve the above objects, there is provided a plasma etching apparatus for a semiconductor apparatus which includes a first filter bypassing a wavelength band of a light emitting signal generated by a main composition forming the first thin film among the light emitting signals generated during the plasma etching process, a first signal converter converting the light emitting signal filtered by the first filter into an electrical signal, a second filter bypassing a predetermined wavelength band near the wavelength band of the light emitting signal, a second signal converter converting a light emitting signal filtered by the second filter into an electrical signal, and a signal subtractor detecting a difference between the electrical signals converted by the first and second signal converter.

The thin film is a diffusion barrier, and the second thin film is a metal film. The first and second signal conversion means a light amplification converter or a light sensor.

The diffusion barrier is formed of TiN, and a light emitting signal generated by a main composition is a light emitting signal from TiCl, and the wavelength band of the light emitting signal bypassed by the first filter is 415˜419 nm, and the wavelength band of the light emitting signal bypassed by the second filter is 422˜427 nm.

The diffusion barrier is formed of TiN, and a light emitting signal generated by a main composition is a light emitting signal from Ti, and the wavelength band of the light emitting signal bypassed by the first filter is 429˜431 nm, and the wavelength band of the light emitting signal bypassed by the second filter is 422˜427 nm.

The diffusion barrier is formed of TiN, and a light emitting signal generated by a main composition is a light emitting signal from Ti, and the wavelength band of the light emitting signal bypassed by the first filter is 465˜468 nm, and the wavelength band of the light emitting signal bypassed by the second filter is 457˜459 nm.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a cross-sectional picture illustrating a metal wiring having a structure formed of an oxide film, diffusion barrier, conductive layer;

FIG. 2 is a perspective view of FIG. 2;

FIGS. 3A and 3C are views illustrating a typical light emitting signal detected in a plasma when forming a metal wiring by etching a stacked silicon oxide film/TiN film/Al film based on a plasma etching method;

FIG. 4 is a view illustrating an etching stop point measuring apparatus adapted to an etching apparatus according to the present invention; and

FIG. 5 is a graph illustrating an electrical signal measured at each portion of an etching stop point measuring apparatus adapted to an etching apparatus according to the present invention.

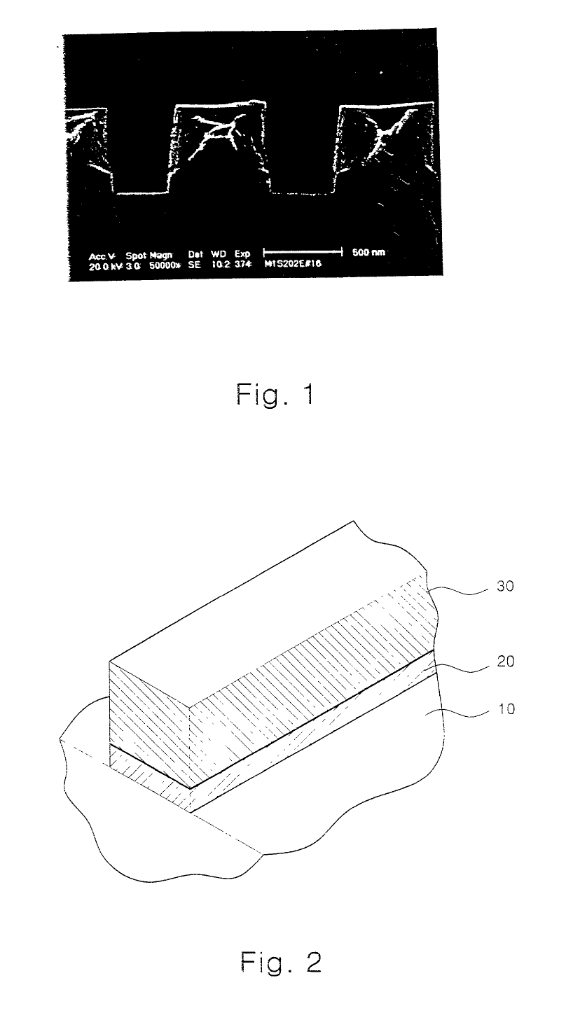

### DETAILED DESCRIPTION OF THE INVENTION

The embodiments of the present invention will be explained with reference to the accompanying drawings.

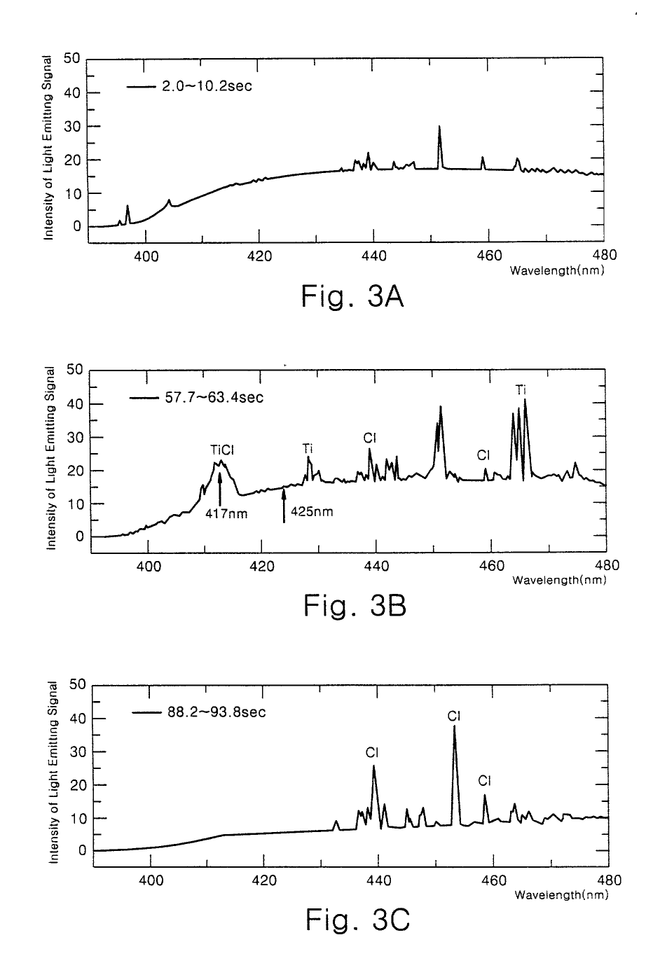

FIGS. 3A and 3C illustrate a typical light emitting signal detected in a plasma when forming a metal wiring by etching a stacked silicon oxide film/TiN film/Al film based on a plasma etching method.

FIG. 3A illustrates a light emitting signal between 2.0˜10.2 seconds after the etching process is performed. In this case, a conductive layer in which a small amount of Cu is added to Al film is etched, and the peak of Al and Cu is detected, and the peak of Cl contained in the etching gas is detected.

FIG. 3B illustrates a light emitting signal between 57.7˜63.4 seconds after the etching process is performed. The TiN film is etched, and the peaks of Ti, Cl, and TiCl which is a compound of Ti and Cl contained in the etching gas are detected. Namely, when etching the diffusion barrier mainly formed of TiN, a light emitting signal emitted from TiCl and Ti in a wavelength band of 415˜419 nm, 429˜413 nm, and 465˜458 nm is detected.

FIG. 3C illustrates a light emitting signal between 88.2˜93.8 seconds after the etching process is performed. Namely, the signals is detected when etching an oxide film which is mainly formed of SiO₂₋ₓ.

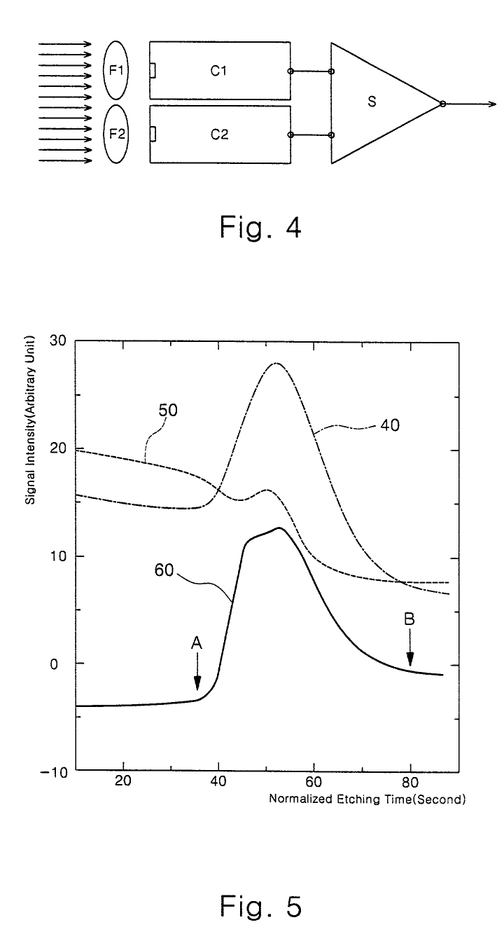

FIG. 4 illustrates an etching stop point measuring apparatus adapted to an etching apparatus according to the present invention.

As shown therein, the optical filters F1 and F2 bypass only the signals having a predetermined wavelength generated from the plasma. The first filter F1 bypasses only a light emitting signal generated based on the main composition forming the diffusion barrier. In the embodiment of the present invention, the first optical filter F1 has a wavelength band of 415˜419 nm, 429˜431 nm, and 465˜458 nm. In addition, the second optical filter F2 uses a signal near the wavelength of the light emitting signal as a reference signal, and the wavelength band of the second optical filter F2 is determined as 422˜427 nm when the wavelength band of the first optical filter F1 is 415˜419 nm, and the wavelength band of the second optical filter F2 is determined as 422˜427 nm when the wavelength band of the first optical filter F1 is 429˜431 nm, and the wavelength band of the second optical filter F2 is determined as 457˜459 nm when the wavelength band of the first optical filter F1 is 465˜468 nm. The light emitting signal passing through the second optical filter F2 selects the wavelength band with no variations based on the time lapse.

The light emitting signals bypassed by the optical filters F1 and F2 are changed into first and second electrical signals by a first optical sensor C1 and a second optical sensor C2. At this time, a photo-multiplier tube may be used as a device for changing the light emitting signal into an electrical signal. The first and second electrical signals are inputted into a signal subtractor S and are converted as a difference between two signals. The thusly converted difference signals is transferred to the control apparatus of the etching apparatus and is used for determining the etching stop point. The signal subtractor is implemented by a semiconductor integration circuit.

FIG. 5 illustrates an electrical signal measured at each portion of an etching stop point measuring apparatus adapted to an etching apparatus according to the present invention.

The light emitting signal emitted from TiCl passes through the first optical filter and first optical sensor having a wavelength band of 415˜419 nm and is inputted into the signal subtractor as a first electrical signal. In FIG. 5, a dotted line represents a normalized etching time of the strength of the first electrical signal 40. The reference light emitting signal passes through the second optical filter and second optical sensor having a wavelength band of 422˜427 nm and is inputted into the signal subtractor as a second electrical signal. The doted line of FIG. 5 represents a normalized etching time of the strength of the second electrical signal 50. The thick line of FIG. 5 represents the normalized etching time of the difference signal 60 obtained after subtracting the second electrical signal from the first electrical signal by the signal subtractor. As shown in FIG. 5, the difference signal is formed in a peak shape having a maximum value. The left side portion A of the peaked shape represents timing when the etching reaches the interfacial surface between the conductive layer and the diffusion barrier, and the right side portion B represents timing when the etching reaches the interfacial surface between the diffusion barrier and the oxide film. Therefore, it is possible to judge the etching start point and etching completion point of the diffusion barrier using the difference signal. Namely, it is possible to accurately determine two etching stop points. The timing when the etching process is stopped is determined by selecting the timing when the etching reaches the left side portion A or the right side portion B in the actual etching process.

In addition, it is known that there is a large variation in the first and second electrical signals, and there is a small variation in the difference signal as a result after the first and second electrical signal and difference signal are measured based on the changes of the plasma activation condition. Namely, it is possible to determine the etching stop point even when the plasma activation condition is varied using the principle of the present invention.

The present invention is explained above based on the structure in which the oxide prevention film of TiN and the conductive layer of Al are sequentially stacked. The present invention is not limited to the above-described embodiments. Namely, the present invention may be implemented for sequentially stacked thin films.

In the conventional etching stop point measuring method, the etching stop point is determined based on only the signal of a single wavelength band. The etching stop point is directly related to the etching byproducts. Since the signal generated in the etching byproducts as well as the signal generated by the plasma activation are contained in the signal of the single wavelength band, the method for determining the etching stop point using the signal of the single wavelength band may cause errors. However, in the present invention, since the etching stop point is determined based on the difference signal of the etching byproducts which is generated by removing the second electrical signal which is a signal generated from the plasma activation source from the first electrical signal which is a signal generated in the etching byproducts and plasma activation source, it is possible to more accurately determine the etching stop point.

Since the etching stop point measuring method using the difference between two wavelength bands is not affected by the plasma activation conditions, it is possible to accurately measure the etching stop point in the currently available etching processes adapting 2 or 3 plasma activation conditions.

When adapting the present invention to the structure in which the lower oxide film, diffusion prevention film, and upper conductive layer are sequentially stacked, since the etching stop point is determined based on the light emitting signal generated by the main composition of the diffusion barrier, it is possible to determine two etching stop points. Therefore, as the metal layer exposed during the etching process is changed from the conducive layer to the diffusion barrier, it is possible to optimize the plasma activation condition. In addition, since the timing when the etching reaches the interface between the diffusion barrier and oxide film is accurately determined, the metal residual substances are substantially removed, and the loss of the oxide film may be minimized.

In addition, in the present invention, since the double etching stop points are accurately determined, and the difference signal outputted from the etching stop point measuring apparatus is a single signal, the apparatus in which the etching apparatus is controlled by the above-described signals may be simplified for thereby enabling a simple software.

Although the preferred embodiments of the present invention have been disclosed for illustrative purposes, those skilled in the art will appreciate that various modifications, additions and substitutions are possible, without departing from the scope and spirit of the invention as recited in the accompanying claims.

What is claimed is:

1. In a method for etching first and second thin films sequentially stacked on an upper portion of a semiconductor substrate using a plasma, a plasma etching method for a semiconductor apparatus, comprising the steps of:
bypassing a light emitting signal of a wavelength band generated by a main composition forming a first thin film among the light emitting signals generated during the plasma etching process and converting the signal into a first electrical signal;
bypassing a signal of a predetermined wavelength band near the wavelength band of the light emitting signal and converting the second electrical signal; and
completing the plasma etching process based on a strength difference between the first and second electrical signals as a reference.

2. The method of claim 1, wherein said firs thin film is a diffusion barrier, and said second thin film is a metal film.

3. The method of claim 2, wherein said diffusion barrier is formed of TiN.

4. The method of claim 3, wherein said light emitting signal generated by a main composition forming the diffusion barrier is a light emitting signal from Ti or TiCl.

5. In an apparatus for etching a first thin film and second thin film sequentially stacked on an upper portion of the semiconductor substrate using a plasma, a plasma etching apparatus for a semiconductor apparatus, comprising:
a first filter means bypassing a wavelength band of a light emitting signal generated by a main composition forming the first thin film among the light emitting signals generated during the plasma etching process;
a first signal conversion means converting the light emitting signal filtered by the first filter means into an electrical signal;
a second filter means bypassing a predetermined wavelength band near the wavelength band of the light emitting signal;
a second signal conversion means converting a light emitting signal filtered by the second filter means into an electrical signal; and
a signal subtraction means detecting a difference between the electrical signals converted by the first and second signal conversion means.

6. The apparatus of claim 5, wherein said thin film is a diffusion barrier, and said second thin film is a metal film.

7. The apparatus of claim 6, wherein said first and second signal conversion means a light amplification converter or a light sensor.

8. The apparatus of claim 6, wherein said diffusion barrier is formed of TiN, and a light emitting signal generated by a main composition is a light emitting signal from TiCl, and the wavelength band of the light emitting signal bypassed by the first filter means is 415˜419 nm, and the wavelength band of the light emitting signal bypassed by the second filter means is 422˜427 nm.

9. The apparatus of claim 7, wherein said diffusion barrier is formed of TiN, and a light emitting signal generated by a main composition is a light emitting signal from Ti, and the wavelength band of the light emitting signal bypassed by the first filter means is 429˜431 nm, and the wavelength band of the light emitting signal bypassed by the second filter means is 422˜427 nm.

10. The apparatus of claim 7, wherein said diffusion barrier is formed of TiN, and a light emitting signal generated by a main composition is a light emitting signal from Ti, and the wavelength band of the light emitting signal bypassed by the first filter means is 465˜468 nm, and the wavelength band of the light emitting signal bypassed by the second filter means is 457˜459 nm.
